(19) United States
(12) Patent Application Publication
(10) Pub. No.: US 2006/0220218 A1
(43) Pub. Date: Oct. 5, 2006

(54) Embedded-type power semiconductor package device

(76) Inventor: Charng-Geng Sheen, Luchu Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/076,957

(22) Filed: Mar. 11, 2005

(51) Int. Cl. H01L 23/48

(52) U.S. Cl. 257/697

(57) ABSTRACT

An embedded-type power semiconductor package device that can clasp an isolating material over a semiconductor die in the inside thereof that through a two-fold strategy reduces the impact force during the embedding process, which includes a pin, a semiconductor die, and a cup. The cup is formed with a cup cavity, an inner wall, a groove and a heat-conductive seat. The heat-conductive seat has an annular retaining wall that is longitudinally protruding from a periphery thereof and a clasping wall that is transversely protruding from a periphery thereof. A cushion sleeve is annularly disposed in the groove and contacted with the inner wall. An insulating material is spread around the semiconductor die and the pin, thereby isolating the semiconductor die from the untouched area. The cup cavity is cast with an isolating material. The clasping wall can hold the isolating material in the cup cavity.

### BACKGROUND OF THE INVENTION

1. Field of the Invention

The present invention relates in general to an embedded-type power semiconductor package device, and more particularly to a diode rectifier, which is usually assembled in a generator in an embedded manner, in an automotive ac generator or an industrial generator for example, to switch alternating current (AC) to direct current (DC).

2. Description of Related Art

The embedded-type power semiconductor package device means a kind of diode rectifier, which is suitable for an automotive ac generator or an industrial ac generator in an embedded manner for switching alternating current (AC) to direct current (DC). The embedded-type power semiconductor package device requires a highly stable interior structure, because it is located in a high-temperature generator, especially in an automobile. Moreover, because it is embedded in a generator in a press-fit manner, it must be able to endure a huge strain during the embedding process.

A related art for an embedded-type power semiconductor package device was issued in R.O.C. U.S. Pat. No. 529,768 on Apr. 21, 2003. Please refer to FIG. 1, which is a cross-sectional view of an embedded-type power semiconductor package device of the related art, including a pin 10a, a semiconductor die 20a, a cup 30a, an insulating material 50a, and isolating material 60a. The semiconductor die 20a is connected with the pin 10a. The cup 30a is formed with a cup cavity 31a, an inner wall 32a, a groove 33a and a heat-conductive seat 34a. The heat-conductive seat 34a is formed with an annular retaining wall 35a, and the heat-conductive seat 34a is connected with the semiconductor die 20a. The insulating material 50a is spread on the semiconductor die 20a and the heat-conductive seat 34a, insulating the semiconductor die 20a from the untouched area. The isolating material 60a is spread on the insulating material 50a.

The embedded-type power semiconductor package device of the related art, in some cases, needs to cast a hard resin 70a (as a molding component) into the cup cavity 31a to protect the semiconductor die 20a. However, the hard resin 70a will harden after being cast. Also, the hard resin 70a escapes easily from the cup cavity 31, because of the compressed force created while embedding the embedded-type power semiconductor package device. Moreover, the hardness of the hard resin 70a easily transmits the strain to the semiconductor die 20a causing damage to the semiconductor die 20a.

Therefore, the embedded-type power semiconductor package device according to the related art still has some inconveniences and disadvantages in the manufacturing and assembling processes, especially in respect to the product that is cast with the hard resin.

The inventor, after investigation and research, thus provides the present invention of logical design for improving the above-mentioned imperfections.

### SUMMARY OF THE INVENTION

An objective of the present invention is to provide an embedded-type power semiconductor package device, which clasps an isolating material over the semiconductor die during the embedding process to prevent the hard-resin from escaping, thereby protecting the semiconductor die and improving the product yield rate.

Another objective of the present invention is to provide an embedded-type power semiconductor package device having two-fold strategy to reduce the impact force created during the embedding process and provides improved protection to the semiconductor die.

In order to achieve the above objectives, the present invention provides an embedded-type power semiconductor package device comprising a pin, a semiconductor die, a cup, a cushion sleeve, an insulating material, and an isolating material. The semiconductor die is connected with the pin. The cup is formed with a cup cavity, an inner wall, a groove and a heat-conductive seat. The heat-conductive seat has an annular retaining wall that is longitudinally protruding from a periphery thereof and a clasping wall that is transversely protruding from a periphery thereof. The heat-conductive seat is connected with the semiconductor die. The cushion sleeve is annularly disposed in the groove and contacted with the inner wall. The insulating material is spread on the semiconductor die and the heat-conductive seat for isolating the semiconductor die from the untouched area. The isolating material is cast in the cup cavity and covered with the insulating material.

### BRIEF DESCRIPTION OF THE DRAWINGS

The invention will be better understood and objectives other than those set forth above will become apparent when consideration is given to the following detailed description thereof. Such description makes reference to the attached drawings, wherein:

FIG. 1 is a cross-sectional view of an embedded-type power semiconductor package device of the relevant art;

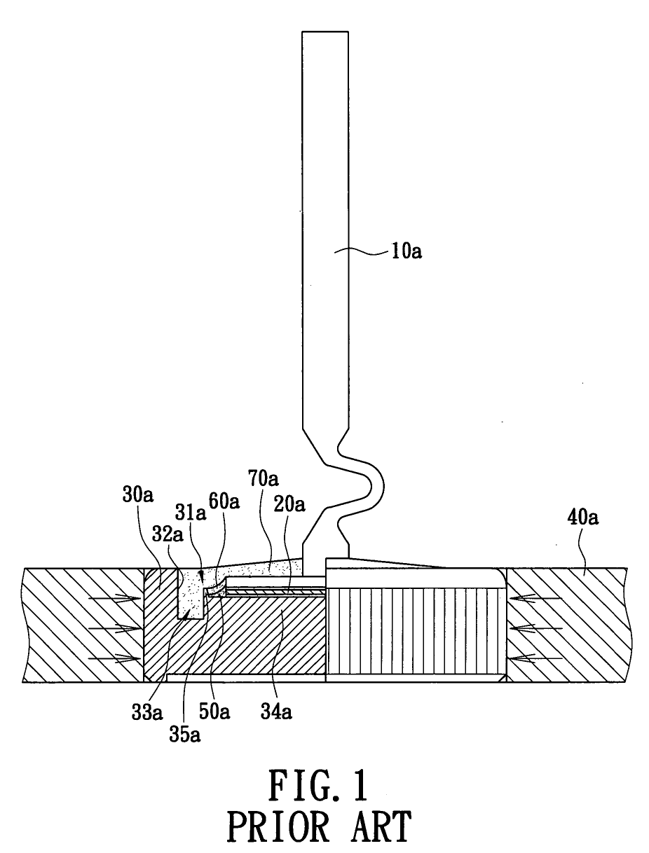

FIG. 2 is a partial cross-sectional view of an embedded-type power semiconductor package device according to the present invention;

FIG. 2A is a magnified diagram of A portion in the FIG. 2 according to the present invention; and

FIG. 3 is a cross-sectional view of a cup for the embedded-type power semiconductor package device according to the present invention.

### DETAILED DESCRIPTION OF PREFERRED EMBODIMENTS

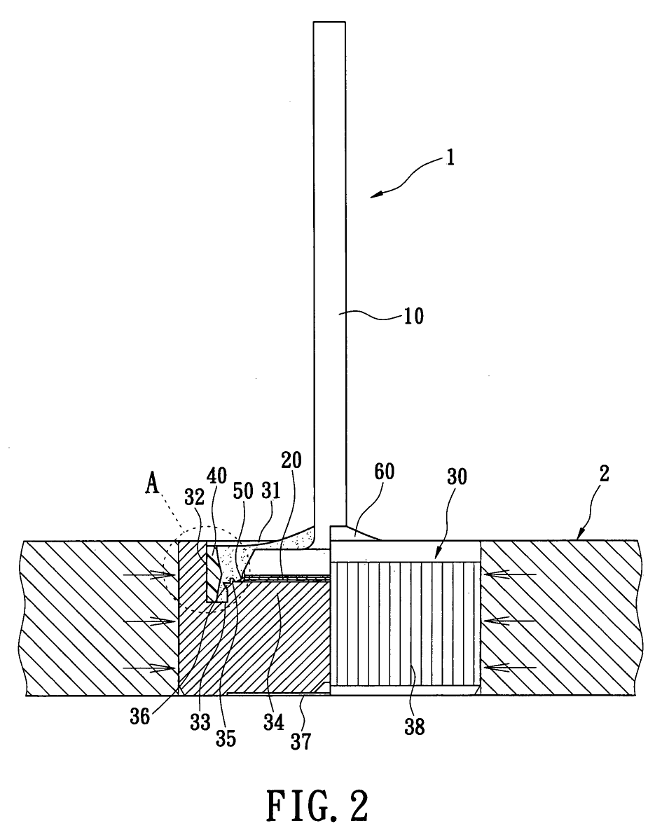

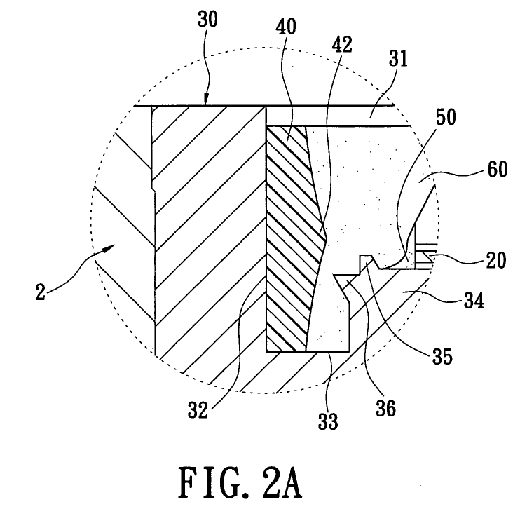

Referring to FIGS. 2 and 2A, which are respectively a partial cross-sectional view of an embedded-type power semiconductor package device and a magnified illustration of a portion of FIG. 2 according to the present invention. The present invention provides an embedded-type power semiconductor package device 1 that is embedded in a substrate 2. The embedded-type power semiconductor package device 1 has a pin 10, a semiconductor die 20, and a cup 30. The pin 10 has a bottom portion that is connected with the semiconductor die 20 and a top portion for connecting with other elements. The semiconductor die 20 is a kind of power semiconductor and is disposed in the cup 30.

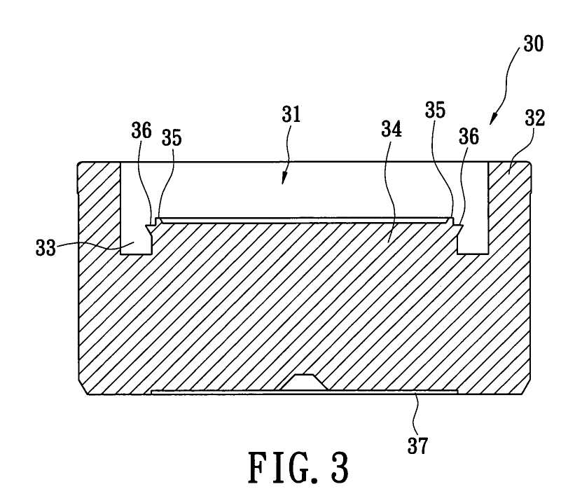

Please refer to FIG. 3, which is a cross-sectional view of a cup for the embedded-type power semiconductor package device according to the present invention. The cup 30 is formed with a cup cavity 31, an inner wall 32, a groove 33 and a heat-conductive seat 34. The heat-conductive seat 34 is protruded upwardly from a bottom of the cup 30 and is formed with a top planar surface for connecting with the semiconductor die 20. The groove 33 is formed annularly around a periphery of the heat-conductive seat 34. The heat-conductive seat 34 has an annular retaining wall 35 that is longitudinally protruding from a periphery thereof and a clasping wall 36 that is transversely protruding from a periphery thereof. The cup 30 is formed with a concave portion 37 on a bottom thereof and a plurality of notches 38 on a peripheral surface. The notches 38 fix the cup 30 in an assembly hole of the substrate 2 in a press-fit manner.

The heat-conductive seat 34, the cup cavity 31 and the groove 33 are symmetrically formed in the cup 30. The semiconductor die 20 is easily positioned at a central portion of the heat-conductive seat 34 through the limitation of the annular retaining wall 35.

The embedded-type power semiconductor package device 1 of the present invention further comprises a cushion sleeve 40, which is annularly disposed in the groove 33 and contacted with the inner wall 32. The cushion sleeve 40 is not adhered to the inner wall 32, and there is a small gap between the cushion sleeve 40 and the inner wall 32. The small gap can prevent the press-in force from transmitting to a soldering face between the semiconductor die 20 and the cup 30, when the embedded-type power semiconductor package device 1 is pressed into the substrate 2. The cushion sleeve 40 is made of flexible plastic, so that it reduces the exterior stress during the embedding process. Because the temperature is about 200 degrees centigrade during casting, the material of the cushion sleeve 40 is preferably one that is resistant to temperatures over 200 degrees centigrade.

An insulating material 50 is spread on an outside of the semiconductor die 20 and the bottom of the pin 10. The annular retaining wall 35 of the heat-conductive seat 34 stops the insulating material 50 from flowing into the groove 33 of the cup 30, so that the semiconductor die 20 are sealed on the heat-conductive seat 34 for insulating the semiconductor die 20 from the untouched area. The insulating material 50 can be polyimide. Polyimide has the characteristics of resistant to high-temperatures and highly insulative. When the semiconductor die 20 are functioning and create a high temperature, the characteristics of the polyimide insulate the semiconductor die 20 from the untouched areas of the heat-conductive seat 34 and the pin 10. Thereby, the semiconductor die 20 reduces electricity leakage, when functioning under either high or low temperatures.

The cup cavity 31 is cast with an isolating material 60. The isolating material 60 covers the insulating material 50 and the bottom of the pin 10, which is used to protect the semiconductor die 20 and prevent moisture from affecting the semiconductor die 20. The material of the isolating material 60 can be epoxy. Epoxy has the characteristic of being waterproof, and enhances the embedded-type power semiconductor package device 1 functioning normally even under high-temperatures or low-temperatures. The clasping wall 36 of the heat-conductive seat 34 can clasp and hold the isolating material 60 in the cup cavity 31, thereby preventing the isolating material 60 from escaping out of the cup 30.

The cushion sleeve 40 of the present invention has one characteristic that deserves to be mentioned. It further comprises an engaging portion 42 on an inner side thereof for engaging with the isolating material 60, thereby preventing the cushion sleeve 40 from escaping out. In this embodiment, as shown in FIG. 2A, the engaging portion 42 of the cushion sleeve 40 is protruding toward the cup cavity 31 and engaged with the isolating material 60. The engaging portion 42 can also be concave, and the isolating material 60 is engaged into the engaging portion 42 to hold the cushion sleeve 40 in the cup cavity 31.

A summary of the characteristics and advantages of the embedded-type power semiconductor package device are as follows:

When the embedded-type power semiconductor package device 1 is embedded in the assembly hole of the substrate 2 in a press-fit manner, the substrate 2 exerts lateral forces to the cup 30. Because the rigidity from the heat-conductive seat 34 to the bottom of the heat-conductive seat 34 is larger than that from the bottom of the groove 33 to the bottom of the cup 30, the curve deformation will be concentrated upon the groove 33 and the bottom of cup 30. Therefore, the semiconductor die 20 of the heat-conductive seat 34 are protected from being damaged, thus ensuring the function of the embedded type package for a power semiconductor device.

Moreover, the embedded-type power semiconductor package device 1 will bear the impact force from up to down, when embedded in the substrate 2. The cushion sleeve 40 of the present invention will mitigate and reduce the impact force first, and prevent the isolating material 60 from being extruded. The isolating material 60 also reduces the impact force passed to the semiconductor die 20. Therefore, the present invention provides the semiconductor die 20 two protective functions.

The present invention provides one more characteristic, which applies to the transverse clasping wall 36 of the heat-conductive seat 34 to clasp and hold the isolating material 60. Even if the cup 30 is deformed and compresses the isolating material 60, the isolating material 60 is still held in the cup cavity 31 and cannot escape out. Therefore, the product yield rate after the assembling processes is ensured.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An embedded-type power semiconductor package device, comprising:
a pin;
a semiconductor die connected with said pin;
a cup formed with a cup cavity, an inner wall, a groove and a heat-conductive seat, said heat-conductive seat having an annular retaining wall longitudinally protruding from a periphery thereof and a clasping wall transversely protruding from a periphery thereof, said heat-conductive seat connected with said semiconductor die;
a cushion sleeve annularly disposed in said groove and contacted with said inner wall;
an insulating material spread on said semiconductor die and said heat-conductive seat for insulating said semiconductor die from an untouched area; and
an isolating material cast in said cup cavity and covered by said insulating material.

2. The embedded-type power semiconductor package device as in claim 1, wherein said heat-conductive seat, said cup cavity and said groove are symmetrically formed in said cup, thereby said semiconductor die is easily positioned at a central portion of said heat-conductive seat through the limitations of said retaining wall.

3. The embedded-type power semiconductor package device as in claim 1, wherein said insulating material is polyimide.

4. The embedded-type power semiconductor package device as in claim 1, wherein said isolating material is epoxy.

5. The embedded-type power semiconductor package device as in claim 1, wherein said cushion sleeve is made of a flexible plastic material and is heatproof to 200 degrees centigrade.

6. The embedded-type power semiconductor package device as in claim 1, wherein said cushion sleeve is formed with an engaging portion on a side thereof for engaging with said isolating material.

7. The embedded-type power semiconductor package device as in claim 6, wherein said engaging portion of said cushion sleeve is protruding toward said cup cavity and engaged with said isolating material.

8. The embedded-type power semiconductor package device as in claim 1, wherein said cup is formed with a concave portion on a bottom thereof.
